(19) United States
(12) Patent Application Publication
(10) Pub. No.: US 2005/0219080 A1
(43) Pub. Date: Oct. 6, 2005

(54) Lossless data embedding

(75) Inventors: Antonius Adrianus Cornelis Maria Kalker, Eindhoven (NL); Franciscus Maria Joannes Willems, Geldrop (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., Eindhoven (NL)

(21) Appl. No.: 10/517,922

(22) PCT Filed: Jun. 11, 2003
(86) PCT No.: PCT/IB03/02569

§ 371 Date: Dec. 14, 2004

(51) Int. Cl. H03M 7/00

(52) U.S. Cl. 341/60

(57) ABSTRACT

An undesirable side effect of watermarking or data-hiding schemes is that the host signal is distorted. This invention discloses a reversible or lossless data-hiding scheme, which allows complete and blind (without additional signaling) reconstruction of the host signal (X). This is achieved by accommodating, in the embedded data (d) of the watermarked signal (Y), restoration data (r) that identifies the host signal, given the composite signal, i.e. the restoration data identifies (24) which modifications the host signal has undergone during embedding (23). The restoration data is accommodated in a portion of the embedding capacity of a conventional embedder (23). The remainder of the capacity is used for embedding payload (w).

### FIELD OF TH INVENTION

The invention relates to a method and arrangement for losslessly embedding data in a host signal. The invention also relates to methods and arrangements for retrieving the data and reconstructing the host signal.

### BACKGROUND OF THE INVASION

An undesirable side effect of many watermarking and data-hiding schemes is that the composite signal (e.g. images, video, audio) into which the auxiliary data has been embedded is distorted. Finding an optimal balance between the amount of embedded data and the induced distortion is therefore an active field of research. There has been considerable progress in understanding the fundamental limits of the capacity-versus-distortion aspect of watermarking and data-hiding schemes.

Sometimes, it is not only desired to embed data with little distortion, but also to be able to remove said distortion completely. A data embedding scheme providing such capability is referred to as a lossless or reversible data-hiding or embedding scheme. Lossless data-hiding schemes are important in cases where no degradation of the original host signal is allowed. This is, for example, true for medical imagery and multimedia archives of valuable original works.

A known lossless data hiding method is disclosed in Jessica Fridrich, Miroslav Goljan and Rui Du, “Lossless Data Embedding for all Image Formats”, Proceedings of SPIE, Security and Watermarking of Multimedia Contents, San Jose, Calif., 2002. In this known method, a feature or subset B of signal X (e.g. the least significant bit plane of a bitmap image, or the least significant bits of specific DCT coefficients of a JPEG image) is extracted from the signal X and subjected to lossless compression. The compressed subset B is concatenated with auxiliary data (payload) and inserted into the signal X in place of the original subset. The method is based on the assumption that the subset B can (i) be losslessly compressed and (ii) randomized while preserving the perceptual quality of signal X.

At the receiver end, the distorted composite signal can be reproduced, using conventional equipment. In order to remove the distortion completely, the concatenated bit stream comprising the compressed subset is extracted and decompressed. The original subset B is subsequently reinserted into the signal X.

The Fridrich et al. article discloses practical examples of lossless data-hiding, but pays little attention to the theoretical limits of lossless embedding schemes.

### OBJECT AND SUMMARY OF THE INVENTION

It is an object of the invention to provide lossless data embedding schemes that are more efficient in a rate-versus-distortion sense.

To this end, the invention provides a method and arrangement for embedding auxiliary data in a host signal, the method comprising the steps of: using a predetermined data embedding method having a given embedding rate and distortion to produce a composite signal; using a portion of said embedding rate to accommodate restoration data identifying the host signal conditioned on said composite signal; and using the remaining embedding rate for embedding said auxiliary data.

The invention exploits the insight that it suffices for a receiver to remove the uncertainty of the original host signal, given the received composite signal. The amount of data, which is required to remove said uncertainty is smaller than the amount of data, which is required to encode the original host signal itself. The inventors have also formulated the theoretical boundaries of lossless data embedding capacity.

### BRIEF DESCRIPTION OF THE DRAWINGS

FIG. 1 shows diagrams representing the boundaries of lossless data embedding schemes.

FIG. 2 shows schematically a diagram of an arrangement for lossless embedding auxiliary data in a host signal according to the invention.

FIG. 3 shows diagrams illustrating the performance of embodiments of lossless data embedding arrangements according to the invention.

FIG. 4 shows a schematic diagram of an arrangement for reconstructing a host signal according to the invention.

FIGS. 5 and 6 illustrate embodiments of accommodating restoration data in a host signal according to the invention.

FIGS. 7 and 8 show diagrams illustrating the difference between symmetrical and asymmetrical channels.

### DESCRIPTION OF PREFERRED EMBODIMENTS

The prior-art compression and bit replacement scheme will first be discussed more generally. The signal source of Fridrich et al. produces a sequence of signal samples, for example, the pixels of an image. The subset B of the signal being compressed (a bit plane, least significant bits of specific DCT coefficients) constitutes a source of binary symbols x₁ . . . x_{N}. It will be assumed that the probabilities p₀=Pr{x=0} and p₁=Pr{x=1} are not equal i.e. the entropy H(p₀)=−p₀log₂(p₀)−p₁log₂(p₁) of the source is less than 1. In that case, the information theory teaches that the sequence of N symbols can be compressed into a shorter sequence y₁ . . . y_{K} of K=N×H(p₀) symbols. A reversible data hiding scheme is now obtained by appending N×(1−H(p₀)) auxiliary data symbols to the sequence y₁ . . . yₖ. For example, if p₀=0.9 and p₁=0.1, the entropy of the source is H(p₀)≈0.47, so that (for large N) only 0.47×N bits are needed to represent the original host symbols. Accordingly, 0.53×N auxiliary data symbols can be embedded as payload into the remainder of the sequence y₁. . . y_{N}. At the decoder end, the original sequence x₁ . . . x_{N} is restored by decompressing y₁ . . . y_{K}. The remainder y_{K+1} . . . y_{N} of the sequence is interpreted as auxiliary data.

The data rate of the Fridrich et al. embedding scheme is R=1−H(p₀) bits/sample. As the bits of the compressed sequence y₁ . . . y_{K} are uncorrelated with those of x₁ . . . x_{N}, and the auxiliary data are randomly chosen, one easily sees that the distortion between x₁ . . . x_{N} and y₁ . . . y_{N} is D=0.5. The distortion of the Fridrich et al. scheme can be reduced by performing the construction above on only a fraction a of the symbols in x₁ . . . x_{N}. This is referred to as time-sharing. Both the data rate and the distortion then decrease by the factor α. The resulting data rate and distortion of this “simple” time-sharing embedding scheme are Rα(1−H(p₀)) and D=α/2, respectively, or:
Rₛᵢₘₚₗₑ(D)=2D(1−H(p₀)) (1)

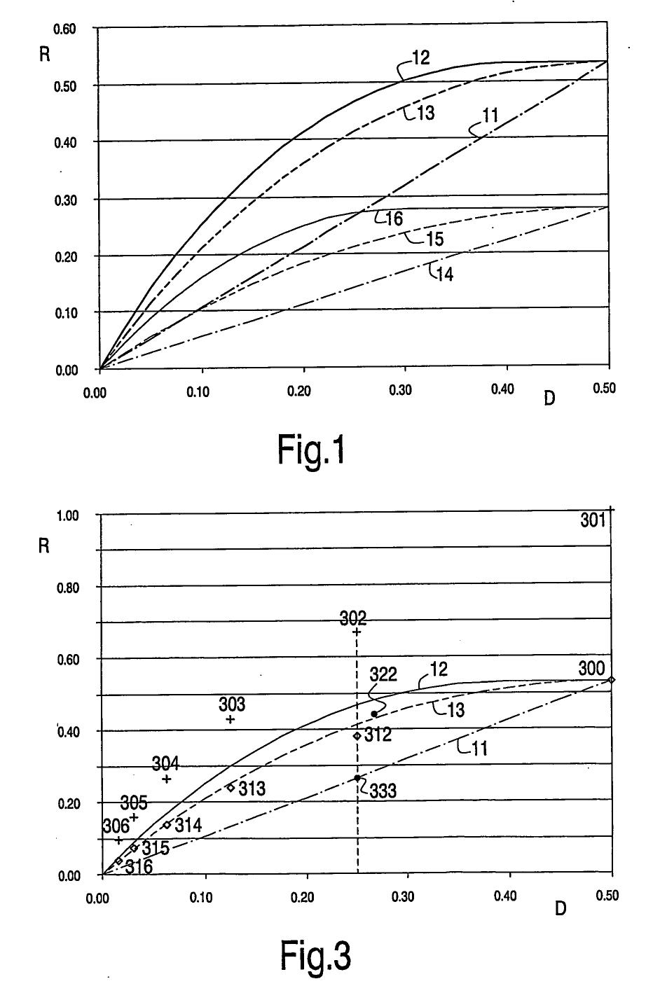

For p₀=0.9, this linear rate-distortion function is shown in FIG. 1 as a dot-and-dash line 11.

The inventors have found that linear equation (1) is not optimal. They have found theoretical boundaries on the capacity of lossless data embedding. More particularly, the achievable data rate Rᵣₑᵥ of a reversible embedding scheme for a memoryless binary source and p₀≧0.5 is, for 0≦D≦0.5:
Rᵣₑᵥ=H(max(p₀−D, 0.5))−H(p₀) (2)

For p=0.9, this rate-distortion function is shown in FIG. 1 as a solid line 12. Equation (2) is generally applicable to asymmetrical channels (the inventors use the notion “channels” for data embedders). For symmetrical channels, the rate is:
R_{sym}=H(p₀+(1−2p₀)D)−H(p₀₎ (3)

For p₀=0.9, this rate-distortion function is shown in FIG. 1 as a dashed line 13. The embedding rate for a symmetrical channel is always between the optimal embedding rate and the timesharing embedding rate. Practical examples of symmetrical and asymmetrical channels will be given later. The lines 11, 12 and 13 in FIG. 1 relate to p₀=0.9 (and p₁=0.1). For illustration, similar lines 14, 15 and 16 are also shown for p₀=0.8.

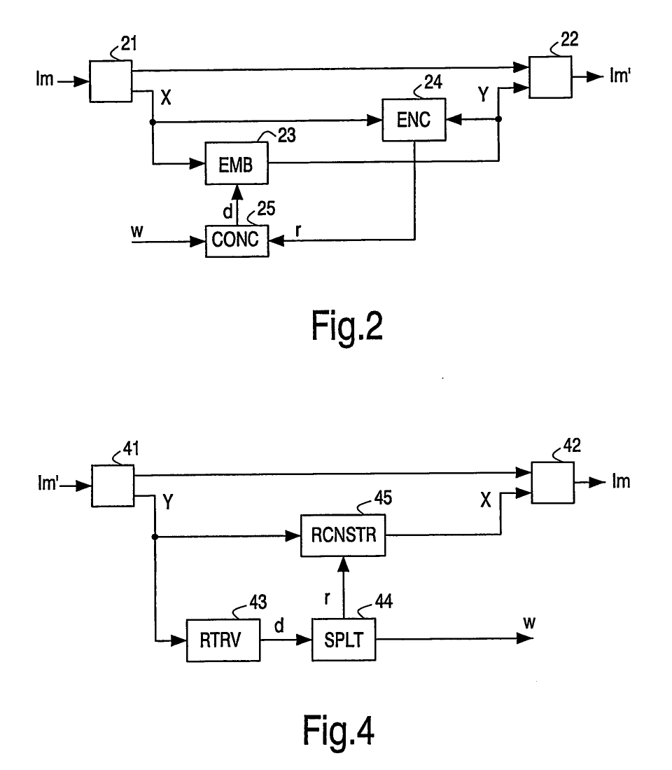

FIG. 2 shows a general schematic diagram of a lossless data embedding arrangement according to the invention. The arrangement receives a digital representation of a perceptual host signal, for example, an image Im. An extraction stage 21 extracts therefrom a sequence of host symbols X={x₁ . . . x_{N}} in which auxiliary data will be embedded. Similarly as in the Fridrich et al. embedding scheme, the host signal can be obtained by extracting from an image a bit plane or the least significant bits of specific DCT coefficients.

The arrangement further comprises a data embedder 23, which is conventional in the sense that this embedder introduces distortion of the host signal. The “squared error” is often used to represent distortion:
D(x,y)=(y−x)²

The embedding process produces a composite signal Y={y₁ . . . y_{N}}. It will initially be assumed that the host signal X and the composite signal Y are binary signals with alphabet {0,1}. The composite signal Y is inserted back into the image by an insertion stage 22 to obtain a watermarked image Im′.

A restoration encoder 24 receives the host signal X and the composite signal Y. The restoration encoder maintains a record of which host symbols have undergone which modification and encodes said information into restoration data r. The expression “which host symbols have undergone which modification” must be interpreted broadly. If the distortion is either D=0 or D=1 (which is the case in this embodiment), then it suffices to identify which symbols have undergone distortion. For other types of embedder 23, the amount of distortion must be encoded as well. It should be noted that the restoration encoder 24 represents a functional feature of the invention. The circuit does not need to be physically present as such. In the practical embodiment of the arrangement being presented hereinafter, the information as to which symbols have been distorted is inherently produced by the embedder 23 itself.

It will be shown that the restoration data rate in bits/symbol is smaller than the embedding rate of embedder 23. The remaining embedding capacity is used for embedding auxiliary data (payload) w. The restoration data r and payload w are concatenated in a concatenation circuit 25. It is the concatenated data d which is applied to the embedder 23 for embedding.

In a preferred embodiment of the arrangement, the embedder 23 operates in accordance with the teachings of an article by M. van Dijk and F. M. J. Willems, “Embedding Information in Grayscale Images”, Proceedings of the 22^{nd} Symposium on Information Theory in the Benelux, Enschede, The Netherlands, May 15-16, 2001, pp. 147-154. In this article, the authors describe lossy embedding schemes that have an efficient rate-distortion ratio. More particularly, a number L (L>1) of host signal samples are grouped together to provide a block or vector of host symbols. The host symbols of a block are modified in such a way that the syndrome of said block represents one or more (but less than L) embedded message symbols d.

The expression “syndrome” is a well-known notion in the field of error correction. In error correction schemes, the syndrome of a received data word is determined by multiplying it with a given matrix. If the syndrome is zero, the data word is correct. If the syndrome is unequal to zero, the non-zero value represents the position (or positions) of erroneous data word symbols. Hamming error correction codes have Hamming distance 3. They allow 1 erroneous data symbol to be corrected. Other codes, such as Golay codes allow plural symbols of a data word to be corrected.

In a mathematical sense, the data embedding method taught by M. van Dijk et al. resembles error correction. In order to embed a message symbol d in a block of L host symbols x₁ . . . x_{L}, the embedder modifies one or more host symbols of said block. Mathematically, an output block y₁ . . . y_{L} is computed which has the desired syndrome and is closest to x₁ . . . x_{L} in a Hamming sense. By way of example, data embedding using a Hamming code with block length L=3 will now be briefly summarized.

To compute the syndrome of a block or vector of 3 bits, the vector is multiplied with the following 3×2 parity check matrix:

$$[ \begin{matrix}0 & 1 & 1 \\ 1 & 0 & 1\end{matrix} ]$$

Note that all mathematical operations are modulo-2 operations. For example, the syndrome of input vector (001) is (11), because

$$[ \begin{matrix}0 & 1 & 1 \\ 1 & 0 & 1\end{matrix} ] \times [ \begin{matrix}0 \\ 0 \\ 1\end{matrix} ] = [ \begin{matrix}1 \\ 1\end{matrix} ]$$

It is this syndrome (11) which represents the embedded data. Obviously, the syndrome of the host vectors is generally not the message to be embedded. One of the host symbols must therefore be modified. If, for example, the message (01) is to be embedded instead of (11), the embedder 23 changes the second host symbol so that original host vector (001) is modified into (011):

$$[ \begin{matrix}0 & 1 & 1 \\ 1 & 0 & 1\end{matrix} ] \times [ \begin{matrix}0 \\ 1 \\ 1\end{matrix} ] = [ \begin{matrix}0 \\ 1\end{matrix} ]$$

The distortion of this embedding scheme per 3 symbols is

$$\frac{1}{4} \cdot {0}^{2} + \frac{3}{4} \cdot {1}^{2} = \frac{3}{4}$$

(probability ¼ that none of the host symbols is changed and probability ¾ that one symbol is changed by ±1), so that the average distortion per symbol is D=¼. The embedding rate is 2 bits per block, i.e. R=⅔ bits/symbol. The corresponding (R,D)-pair is shown as a + sign denoted 302 in FIG. 3.

In a similar manner, 3 data bits can be embedded in a block of 7 signal symbols, 4 bits can be embedded in 15 signal symbols, etc. More generally, the Hamming code based embedding schemes allow m message symbols to be embedded in blocks of L=2^{m}−1 host symbols by modifying at most 1 host symbol. The embedding rate is

$$R = \frac{m}{{2}^{m} - 1} ,$$

and the distortion is

$$D = \frac{1}{{2}^{m}} .$$

FIG. 3 shows the corresponding (R,D)-pairs of this (lossy, irreversible) embedding scheme for m=2,3, . . . ,6 as + signs denoted 302, 303, . . . , 306. The (R,D)-pair for m=1 (which is simple bit replacement) is also shown as + sign denoted 301. Note that the (R,D) values do not depend on the entropy H(p) of the binary source. FIG. 3 also shows the (R,D) pair 300 (R=0.53 bits/symbol, D=0.5) of the Fridrich et al. lossless embedding scheme for p₀=0.9. The theoretical boundaries 11, 12 and 13 of lossless embedding schemes for p₀=0.9 (cf. FIG. 1) are also shown in FIG. 3 for reference.

According to the invention, a portion of the embedded message data bits d is now used to identify whether one of the signal samples has been modified and, if so, which sample that is. For the Hamming codes with block length 3 (m=2, L=3), there are 4 possibilities: none of the three host symbols has been changed, the first symbol has been modified, the second symbol has been modified, or the third symbol has been modified. If the entropy H(p) of the signal source is equal to 1, then all events have equal probabilities. In that case, both embedded message bits per block are required for restoration. However, if the entropy H(p) of the signal source is unequal to 1, then the events have different probabilities, and less than m restoration bits are required. This leaves space to embed ‘real’ auxiliary data bits (also referred to as payload) in the blocks of host symbols.

Similarly as in the Fridrich et al. example, it will be assumed that p₀=0.9. Accordingly, the probability p(x=000) that the source produces host vector (000) is (0.9)³≈0.729. The probability p(x=001) that the source produces host vector (001) is (0.9)²×(0.1)≈0.081, etc. Assume that the embedder 23 of the arrangement has produced a composite vector y=000. The original host vector x could have been (000). In that case, none of the original signal samples has been modified. However, the original host vector could also have been (001), (010), or (100). In that case, one of the host symbols has been modified. The probability that the host vector was x=000, given the generation of y=000, is:

$$p ( x = 000 \vert y = 000 ) = \frac{p ( x = 000 )}{p ( x = 000 ) + p ( x = 001 ) + p ( x = 010 ) + p ( x = 100 )} = 0.75$$

In a similar manner, the probabilities that y=000 originates from host vector (001), (010) or (100) can be computed. This yields:
p(x=001|y=000)=0.083
p(x=010|y=000)=0.083
p(x=100|y=000)=0.083

Each composite vector y has thus an associated set of conditional probabilities p(x|y). They are summarized in the following Table. The Table also includes, for each block y, the corresponding conditional entropy H(x|y). Said conditional entropy represents the uncertainty of original vector x, given the vector y. The Table also includes, for each vector y, the probability p(y), assuming that the messages 00, 01, 10 and 11 have equal probabilities ¼. For example, the probability p(y=000) has been computed as follows:

$p ( y = 000 ) = \frac{1}{4} p ( x = 000 ) + \frac{1}{4} p ( x = 001 ) + \frac{1}{4} p ( x = 010 ) + \frac{1}{4} p ( x = 100 ) = 0.2430$

| | | | p(x\|y) | | | | | | | |
|---|---|---|---|---|---|---|---|---|---|---|
| x | syndrome | p(x) | y = 000 | y = 001 | y = 010 | y = 011 | y = 100 | y = 101 | y = 110 | y = 111 |
| 000 | 00 | 0.729 | 0.7500 | 0.8804 | 0.8804 | | 0.8804 | | | |
| 001 | 11 | 0.081 | 0.0833 | 0.0978 | | 0.4709 | | 0.4709 | | |
| 010 | 10 | 0.081 | 0.0833 | | 0.0978 | 0.4709 | | | 0.4709 | |
| 011 | 01 | 0.009 | | 0.0109 | 0.0109 | 0.0523 | | | | 0.3214 |
| 100 | 01 | 0.081 | 0.0833 | | | | 0.0978 | 0.4709 | 0.4709 | |
| 101 | 10 | 0.009 | | 0.0109 | | | 0.0109 | 0.0523 | | 0.3214 |
| 110 | 11 | 0.009 | | | 0.0109 | | 0.0109 | | 0.0523 | 0.3214 |
| 111 | 00 | 0.001 | | | | 0.0058 | | 0.0058 | 0.0058 | 0.0357 |
| | | H(x\|y) = | 1.2075 | 0.6316 | 0.6316 | 1.2891 | 0.6316 | 1.2891 | 1.2891 | 1.7506 |
| | | p(y) = | 0.2430 | 0.2070 | 0.2070 | 0.0430 | 0.2070 | 0.0430 | 0.0430 | 0.0070 |

The conditional entropy H(X|Y) of the source, averaged over all blocks y, represents the number of bits to reconstruct x, given y. In the present example, said average entropy equals:

$$H ( X \vert Y ) = {\sum }_{y} p ( y ) H ( x \vert y ) = 0.8642 bits / block$$

Accordingly, 0.8642 restoration bits per block are required to identify the original block. This leaves 2−0.8642=1.1358 bits/block for embedding payload. The data rate R is thus:

$$R = \frac{1.1358}{3} = 0.3786 bits / symbol .$$

Note that the distortion D of the composite signal is not affected by the particular meaning that has now been assigned to the embedded data d. As described before, the distortion of this lossless embedding scheme is:
D=¼

The corresponding (R,D) pair is shown as a ⋄ sign denoted 312 in FIG. 3. It will be appreciated that this lossless embedding scheme has a considerably higher embedding rate R than the Fridrich et al. lossless embedding scheme having the same distortion (cf. 333). In a similar manner, the rate-distortion pairs for Hamming codes having lengths 7, 15, 31, 63, etc. can be computed. FIG. 3 shows the corresponding (R,D)-pairs for m=3, . . . ,6 as ⋄ signs denoted 313, . . . , 316.

FIG. 4 shows a schematic diagram of an arrangement for reconstructing the original host signal from a received composite signal. The arrangement receives the watermarked image Im′. The received image is a slightly distorted version of the original image Im. It can be directly applied to a reproduction device for display. The arrangement further comprises an extraction stage 41, which extracts from the received image the composite signal Y={y₁ . . . y_{N}} (e.g. a given bit plane) in which the data d has been embedded. The extraction stage 41 is identical to the extraction stage 21 of the embedding arrangement which is shown in FIG. 2.

The composite signal Y is applied to a data retrieval circuit 43, which retrieves the data d being embedded in the composite signal. In the preferred embodiment, wherein de data has been embedded using Hamming codes of length L, the retrieval circuit 43 determines the syndrome of each block of symbols y₁ . . . y_{L}. The extracted data is a concatenation of payload w and restoration bits r. They are separated in a splitter 44, which performs the reverse operation of concatenation circuit 26, which is shown in FIG. 2. The payload w is thus retrieved.

The restoration bits r and the composite signal Y are used, by a reconstruction unit 45, to reconstruct the original host signal X. The reconstruction unit is arranged to undo the modification(s) applied to the original host signal X=x₁ . . . x_{N}. In the preferred embodiment, the restoration data r identifies whether one of the symbols in a block Y has been modified and, if so, which symbol that is. In more general terms, the restoration data identifies the distortion D of the symbols y₁ . . . y_{N}. The reconstructed host signal X is finally inserted back into the image by an insertion stage 42 to obtain the original image Im. The insertion stage 42 is identical to the insertion stage 21 of the embedding arrangement which is shown in FIG. 2.

In the embodiment described above, it has been assumed that the host signal X, the composite signal Y, and the data symbols are binary signals with alphabet {0,1}. However, the invention is not restricted to binary signals. For example, a ternary embedding scheme as disclosed in the van Dijk et al. article may be used as well. In a ternary data embedder, the data symbols d belong to an alphabet {0,1,2}. More particularly:
signal sample values y=0,3,6, . . . represent message symbol d=y mod 3=0,
signal sample values y=1,4,7, . . . represent message symbol d=y mod 3=1, and
signal sample values y=2,5,8, . . . represent message symbol d=y mod 3=2.

The data embedder 23 (see FIG. 2) now receives the original image signal (the circuits 21 and 22 are redundant), and modifies the least significant portion of a signal sample xᵢ such that the data embedded in modified sample yᵢ is d. In a similar manner as described for binary embedding, ternary symbols can also be embedded in groups of host symbols. It is again possible to do this by using (ternary) Hamming codes or a (ternary) Golay code. Examples thereof are described in Applicant's non-prepublished International patent application IB02/01702 (Applicant's docket PHNL010358).

In yet another data embedding scheme, the message symbols d are embedded in pairs of signal samples. In this scheme, the two-dimensional symbol space of signal samples (xₐ,x_{b}) is “colored” with 5 colors. Each point on the grid denotes a pair of signal samples, and has a color different from its neighbors. The colors are numbered 0 . . . 4, and each color represents a message symbol d∈{0,1,2,3,4}. In this embodiment, the embedder 23 checks whether (xₐ,x_{b}) has the color d to be embedded. If that is not the case, it changes the symbol pair (xₐ,x_{b}) such that the modified pair has the color d. It will be appreciated that the two-dimensional embedding scheme can be extended to more dimensions. In a three-dimensional grid, for example, each point cannot only be “moved” to the four neighbors in the same layer, but also up or down. Seven colors, i.e. seven message symbols, are now available.

Practical embodiments of particular methods of accommodating the restoration data r in the data d to be embedded will now be described. In this respect, it is to be noted that the embedding rate R that can be attained using a given embedder 23 (such as R=0.3786 bits/symbol for binary embedding using Hamming codes with block length 3), is maximal. The embedding rate can be approached for long sequences (large N) of host signal samples.

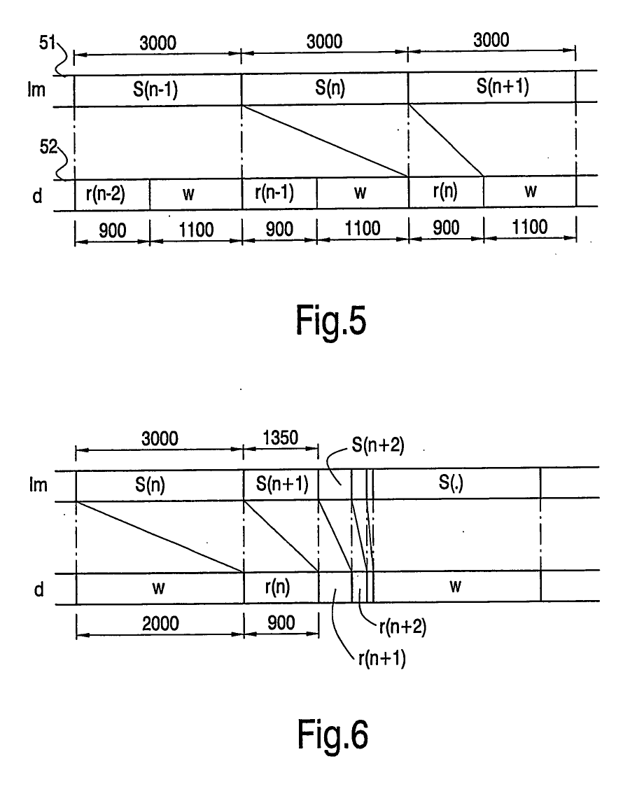

In a first embodiment of the method according to the invention, the host signal is divided into segments that are large enough. The restoration data for each segment is accommodated in a subsequent segment. The remaining capacity is used for embedding payload. This is shown in FIG. 5, where numeral 51 denotes the original host signal Im. The signal is divided into segments S(n), each comprising a given number of signal samples (here image pixels). Numeral 52 denotes the embedded data stream d in time alignment with the signal. As has been illustrated, the restoration bits r(n) for segment S(n) have been embedded in segment S(n+1). The remaining portion of segment S(n+1) is used for accommodating payload w. Note that the precise number of restoration bits may vary from segment to segment. It is advantageous to identify the boundary between restoration bits r and payload w in a segment, for example, by providing each series of restoration bits with an appropriate end-code.

The figures shown in FIG. 5 are illustrative only. Let the segment length be N (here N=3000) signal symbols. The embedder 23 (see FIG. 2) is based on Hamming codes with block length 3. This embedder has an embedding rate R (here R=⅔) bits/symbol, and allows R×N (here 2000) bits to be embedded in each segment. The entropy of the source is H(X|Y) (here 0.8642/3≈0.3 bits per symbol) for a given probability p₀ (here 0.9). The number of restoration bits to remove the uncertainty of segment X, given Y, is H(X|Y)×N (here 0.3 bits/symbol×3000 symbols=900 bits). This leaves R×N−H(X|Y)×N (here 2000−900=1100) bits for payload.

FIG. 6 shows an alternative embodiment for accommodating the restoration bits. In this embodiment, a segment S(n) with a given initial length is provided with payload w only. The restoration bits r(n) for segment S(n) are accommodated in a subsequent segment S(n+1). The subsequent segment S(n+1) is now assigned a length that is required to accommodate the restoration bits r(n). The segment S(n+1) requires anew number of restoration bits r(n+1) to be embedded in a yet further segment S(n+2), etc. This process is repeated a number of times, e.g. until the subsequent segment is smaller than a given threshold. The whole process is then repeated for a new segment S(.) with the given initial length.

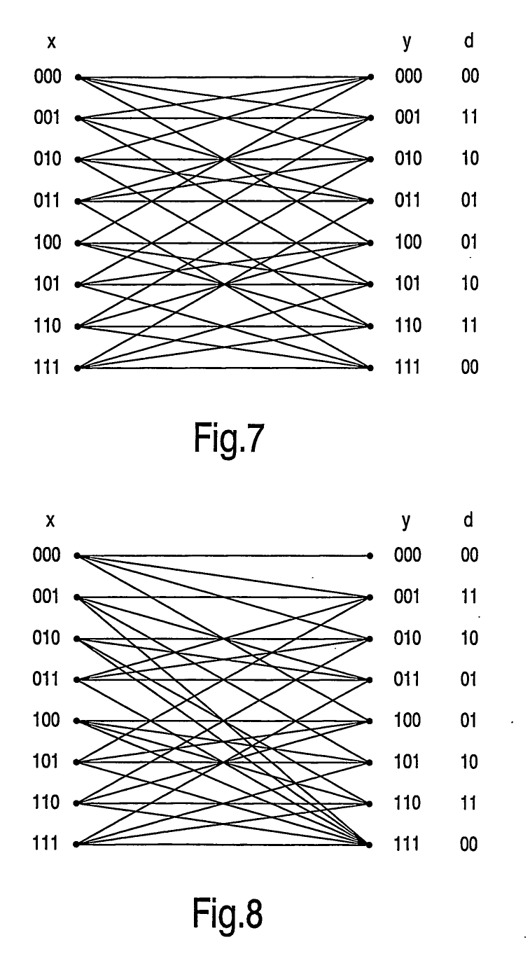

A data embedder, which turns an input symbol or vector X into an output symbol or vector Y represents a “channel”. The data embedders described thusfar constitute a symmetrical channel. This can be seen in FIG. 7, which is a graphical representation of the data embedder based on Hamming codes having block length 3 as described before. FIG. 8 is the graphical representation of an asymmetrical channel. This particular example is obtained by modifying input vectors (001), (010) and (100) into y=(111) instead of y=(000), when d=00 is to be embedded (1's are preferably not changed into 0's). The embedding rate of this embedding scheme is R=0.4335 bits/symbol (cf. rate R=0.3786 of the corresponding symmetrical channel). Because 2 bits of a vector, instead of 1 bit, are now sometimes changed, the distortion is slightly greater. In this case, the distortion is D=0.2701 (cf. D=0.25 of the symmetrical channel). Reference numeral 322 in FIG. 3 denotes the corresponding (R,D)-pair. As can be seen in this Figure, the performance of the asymmetrical channel lies between boundary lines 12 and 13.

The invention can be summarized as follows. An undesirable side effect of watermarking or data-hiding schemes is which the host signal is distorted. This invention discloses a reversible or lossless data-hiding scheme, which allows complete and blind (without additional signaling) reconstruction of the host signal (X). This is achieved by accommodating, in the embedded data (d) of the watermarked signal (Y), restoration data (r) that identifies the host signal, given the composite signal, i.e. the restoration data identifies (24) which modifications the host signal has undergone during embedding (23). The restoration data is accommodated in a portion of the embedding capacity of a conventional embedder (23). The remainder of the capacity is used for embedding payload (w).

1. A method of embedding auxiliary data in a host signal, the method comprising the steps of:
using a predetermined data embedding method having a given embedding rate and distortion to produce a composite signal;
using a portion of said embedding rate to accommodate restoration data identifying the host signal conditioned on said composite signal; and
using the remaining embedding rate for embedding said auxiliary data.

2. A method as claimed in claim 1, comprising the steps of:
dividing the host signal into successive segments;
applying the predetermined data embedding method to said segments;
accommodating in a segment the restoration data for a previous segment.

3. A method as claimed in claim 2, wherein each segment comprises the restoration data for said previous segment as well as auxiliary data.

4. A method as claimed in claim 2, comprising the steps of:
(a) accommodating auxiliary data only in a segment of a given length;
(b) accommodating, in a subsequent segment, restoration data only for the previous segment
(c) adapting the length of said subsequent segment to the amount of restoration data being embedded therein;
(d) repeating steps (b) and (c) a predetermined number of times.

5. A method as claimed in claim 4, wherein said step (d) comprises repeating steps (b) and (c) until the length of the subsequent segment is smaller than a predetermined threshold.

6. An arrangement for embedding auxiliary data (w) in a host signal (X), the arrangement comprising:
a predetermined data embedder (23) having a given embedding rate and distortion to produce a composite signal (Y) with embedded data (d);
means (24,25) for generating restoration data (r) identifying the host signal (X) conditioned on the composite signal (Y); and
means (26) for accommodating said restoration data (r) in a portion of said embedded data (d) and said auxiliary data (w) in the remaining portion of said embedded data.

7. A method of reconstructing a host signal from a composite signal representing a distorted version of said host signal with data embedded therein, the method comprising the steps of:
retrieving the embedded data from the composite signal;
splitting the embedded data into restoration data and auxiliary data;
reconstructing the host signal using the reconstruction data, given the composite signal.

8. A method as claimed in claim 7, comprising the steps of:
dividing the composite signal into successive segments;
using the restoration data accommodated in a segment for reconstructing a previous segment of the host signal.

9. A method as claimed in claim 8, wherein each segment of the composite signal comprises the restoration data for said previous segment of the host signal as well as auxiliary data.

10. An arrangement for reconstructing a host signal (X) from a composite signal (Y) representing a distorted version of said host signal with data (d) embedded therein, the arrangement comprising:
means (43) for retrieving the embedded data (d) from the composite signal (Y);
splitting means (44) for splitting the embedded data (d) into restoration data (r) and auxiliary data (w);
reconstruction means (46) for reconstructing the host signal (X) using the reconstruction data (r), given the composite signal (Y).

11. A composite information signal (Y) with embedded data (d) comprising restoration data (r) and auxiliary data (w), said restoration data identifying the distortion of a host signal (X) conditioned on said composite signal.
